(19) United States
(12) Patent Application Publication
(10) Pub. No.: US 2021/0013178 A1
(43) Pub. Date: Jan. 14, 2021

(54) ELECTRONIC MODULE AND ELECTRONIC DEVICE

(71) Applicant: FUJITSU LIMITED, Kawasaki-shi (JP)

(72) Inventors: TERU NAKANISHI, Isehara (JP); Daijiro Ishibashi, Yokohama (JP); Shinya Sasaki, Ebina (JP); Yukiko Oshikubo, Atsugi (JP); Yoshihiro NAKATA, Atsugi (JP)

(73) Assignee: FUJITSU LIMITED, Kawasaki-shi (JP)

(21) Appl. No.: 16/923,141

(22) Filed: Jul. 8, 2020

(30) Foreign Application Priority Data
Jul. 10, 2019 (JP) 2019-128659

(51) Int. Cl. H01L 25/065; H01L 23/367; H01L 23/373

(52) U.S. Cl. CPC H01L 25/0655; H01Q 21/065; H01L 23/373; H01L 23/3675

(57) ABSTRACT

An electronic module includes: a plurality of heat generating members provided over a first surface of a board; a frame joined to the first surface of the board and provided between the plurality of heat generating members that are arranged; and a lid configured to cover the first surface of the board and thermally coupled to each of the plurality of heat generating members, the frame being a grid-shaped frame or a mesh-shaped frame.

### CROSS-REFERENCE TO RELATED APPLICATION

This application is based upon and claims the benefit of priority of the prior Japanese Patent Application No. 2019-128659, filed on Jul. 10, 2019, the entire contents of which are incorporated herein by reference.

### FIELD

The disclosed technique is related to an electronic module and an electronic device.

### BACKGROUND

As techniques related to an electronic module in which a plurality of heat-generating components are mounted over a board, the following techniques are known. For example, an electronic apparatus has been described. This electronic apparatus includes a heat dissipation member that is disposed in a housing of the electronic device and that disperses and dissipates heat generated by a plurality of heat generating elements mounted over a board in the housing. The heat dissipation member is disposed so as to face the board, includes separator portions that thermally separate the heat generating elements, and is formed of a resin molded material containing carbon fiber having electrical conductivity and thermal conductivity.

Also, in a known hybrid integrated circuit, a plurality of individual components are mounted over a board and airtightly sealed by a cap. The individual components are separated into groups of predetermined numbers of the individual components and airtightly sealed by the cap. For this, the cap is partitioned by a plurality of partitioning projection walls into a plurality of space portions.

Examples of the related art include Japanese Laid-open Patent Publication No. 2004-207661 and Japanese Unexamined Utility Model Registration Application Publication No. 60-88551.

### SUMMARY

According to an aspect of the embodiments, an electronic module includes: a plurality of heat generating members provided over a first surface of a board; a frame joined to the first surface of the board and provided between the plurality of heat generating members that are arranged; and a lid configured to cover the first surface of the board and thermally coupled to each of the plurality of heat generating members.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a sectional view illustrating an example of a configuration of an electronic module according to an embodiment of the disclosed technique;

FIG. 2 is an exploded perspective view of the configuration of the electronic module according to the embodiment of the disclosed technique;

FIG. 3 is a plan view of the electronic module according to the embodiment of the disclosed technique with a lid removed;

FIG. 4A is a plan view illustrating an example of a conductor pattern formed over a first main surface of the board according to the embodiment of the disclosed technique;

FIG. 48 is a plan view illustrating an example of a conductor pattern formed over a second main surface of the board according to the embodiment of the disclosed technique;

FIG. 5A is a perspective view illustrating an example of a configuration of a frame according to the embodiment of the disclosed technique;

FIG. 5B is a perspective view illustrating the example of the configuration of the frame according to the embodiment of the disclosed technique;

FIG. 6A is a sectional view illustrating an example of a method of manufacturing the electronic module according to the embodiment of the disclosed technique;

FIG. 6B is a sectional view illustrating the example of the method of manufacturing the electronic module according to the embodiment of the disclosed technique;

FIG. 6C is a sectional view illustrating the example of the method of manufacturing the electronic module according to the embodiment of the disclosed technique;

FIG. 6D is a sectional view illustrating the example of the method of manufacturing the electronic module according to the embodiment of the disclosed technique;

FIG. 7 is a sectional view illustrating an example of a configuration of an electronic module according to a comparative example;

FIG. 8 is a diagram illustrating a simulation model of the electronic module according to the embodiment of the disclosed technique;

FIG. 9 is a graph illustrating the relationship between the Young's modulus of the frame and a deformation amount improvement rate of the board;

FIG. 10 is a graph illustrating the relationship between the thermal expansion coefficient of the frame and the deformation amount improvement rate of the board;

FIG. 11 is a plan view illustrating an example of a configuration of an electronic module according to an embodiment of the disclosed technique;

FIG. 12 is a perspective view illustrating an example of a configuration of an electronic device according to an embodiment of the disclosed technique; and

FIG. 13 is a block diagram illustrating an example of a functional configuration of the electronic device according to the embodiment of the disclosed technique.

### DESCRIPTION OF EMBODIMENTS

As a technique of next-generation wireless communication, there is a known technique in which a plurality of antennas are disposed over a board, and a beam-shaped radio wave is radiated toward wireless terminals by controlling the phases of signals transmitted from the antennas. With this technique, high-speed, large-capacity communication may be realized.

Signal processing circuits such as phase shifters and amplifiers are mounted over the board so as to correspond to the respective antennas. For example, when a fan-out wafer level package (FOWLP) is used as a package for a signal processing circuit, transmission loss of the signals may be reduced, and further, high-density mounting may be achieved. An electronic module that includes antennas and electronic components including a signal processing circuits over a board as described above preferably includes a heat dissipation mechanism that radiates heat generated by the electronic components to the outside so as to avoid damage caused by the heat generated by the electronic components.

The heat dissipation mechanism is configured by, for example, joining a lid formed of a material having a high thermal conductivity to the electronic components that are heat sources. In order to ensure heat dissipation properties, it is preferable that the lid and the electronic components be in close contact with each other, and it is preferable that a material having a comparatively high thermal conductivity such as solder and thermal grease be used in joining the lid and the electronic component.

In an electronic module configured as described above, when the amount of heat generation of the electronic components mounted over the board increases, the board may be deformed (bent) by the difference in thermal expansion coefficient between the electronic components and the board, thereby breaking the joining between the lid and the electronic components. As a result, the thermal dissipation function of the lid is not necessarily effectively produced, and accordingly, the electronic components may be damaged by the heat generation.

Hereinafter, embodiments of the present disclosure will be described with reference to the drawings. In the drawings, substantially the same or equal elements or parts are denoted by the same reference numerals.

### First Embodiment

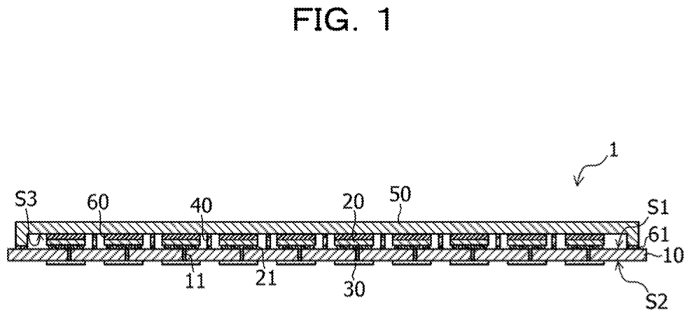

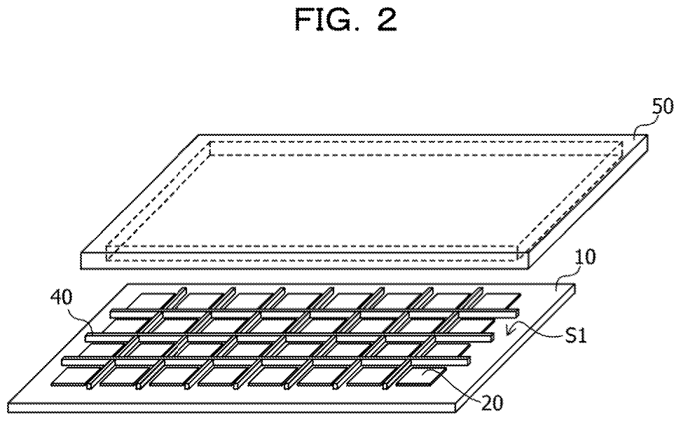

FIG. 1 is a sectional view illustrating an example of a configuration of an electronic module 1 according to a first embodiment of the disclosed technique. The electronic module 1 is used to configure an antenna and a radio frequency (RF) unit of a communication device that performs wireless communication. The electronic module 1 includes a board 10, a plurality of electronic components 20, a plurality of antennas 30, a lid 50, and a frame 40.

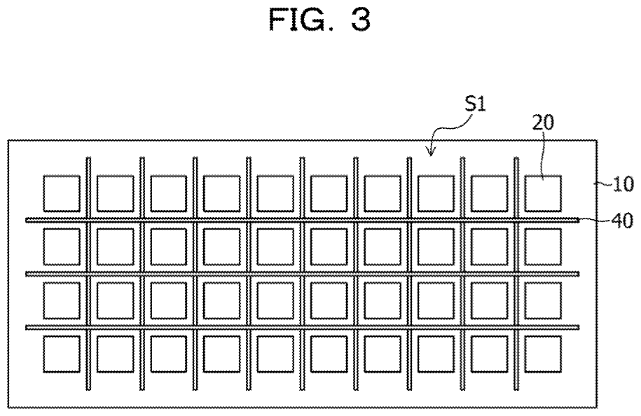

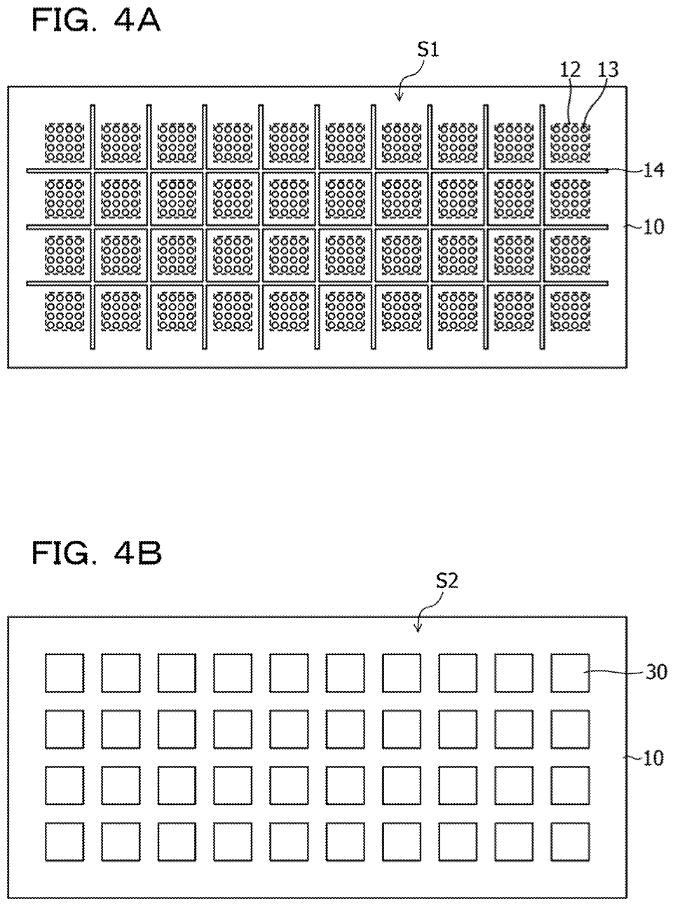

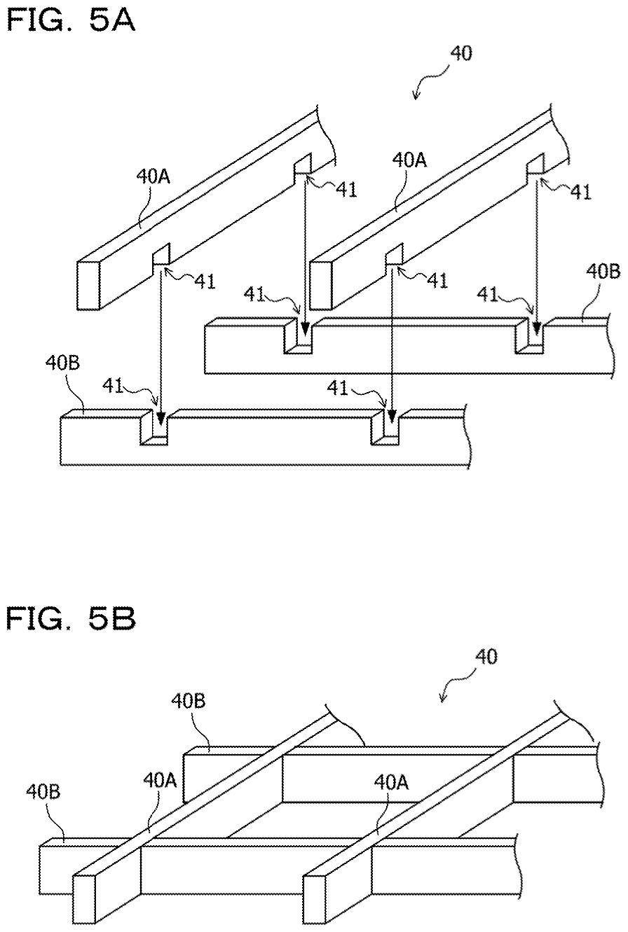

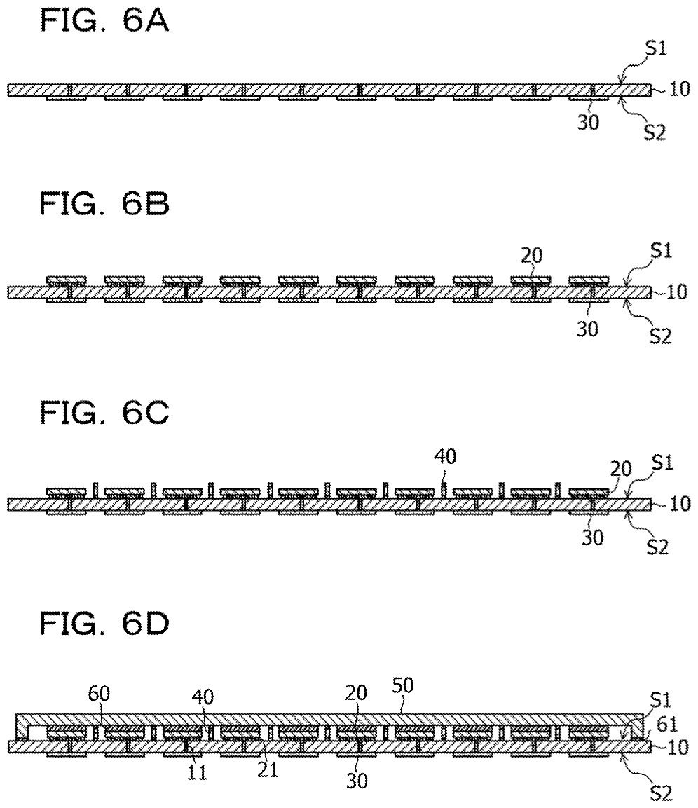

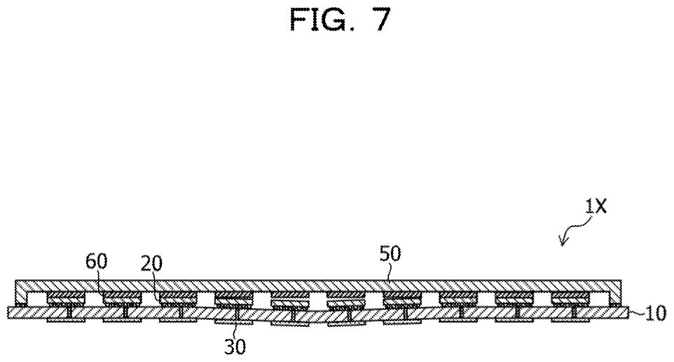

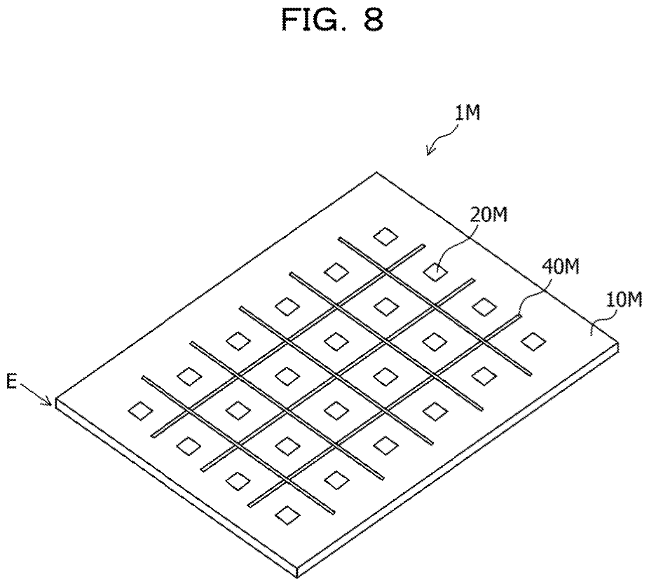

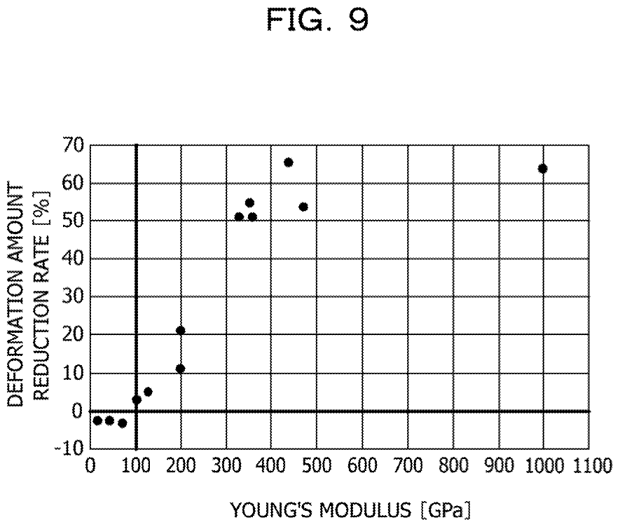

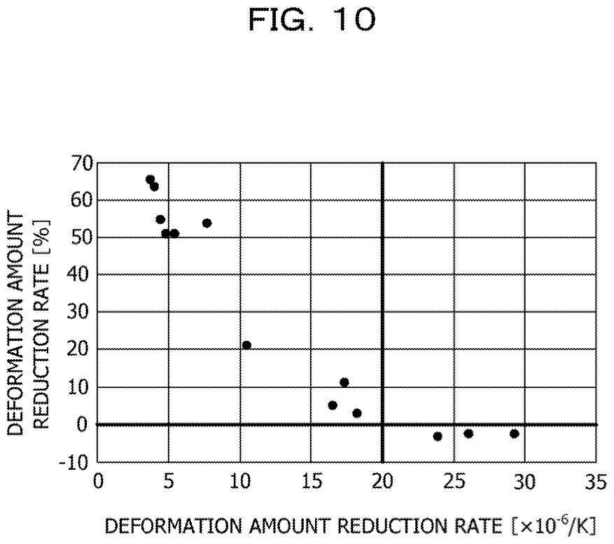

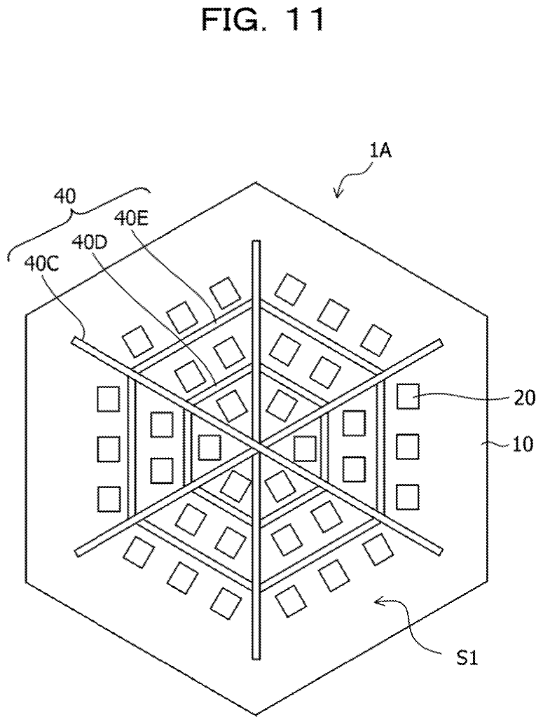

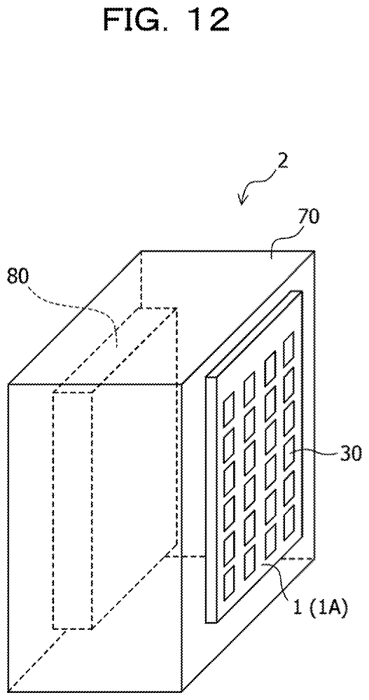

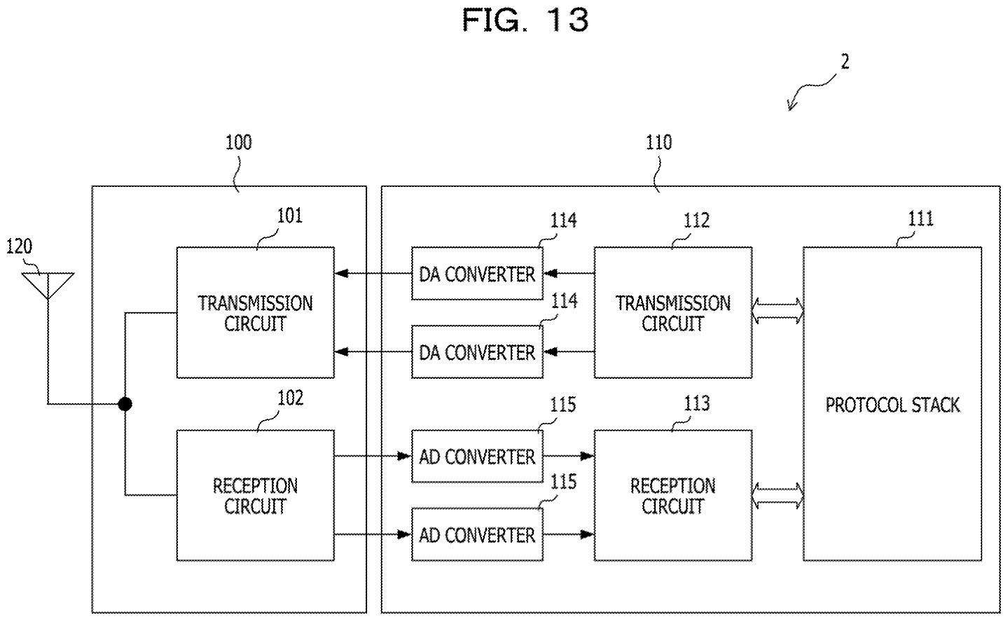

FIG. 2 is an exploded perspective view of the configuration of the electronic module 1, illustrating the lid 50 separated from other components. FIG. 3 is a plan view of the electronic module 1 with the lid 50 removed. FIG. 4A is a plan view illustrating an example of a conductor pattern formed over a first main surface S1 of the board 10. FIG. 4B is a plan view illustrating an example of a conductor pattern formed over a second main surface S2 of the board 10 opposite the first main surface S1.

The board 10 is formed of an insulator such as, for example, a glass epoxy resin. The electronic components 20 are mounted over the first main surface S1 of the board 10 so as to form a matrix along the sides of the rectangular board 10. As illustrated in FIG. 4A, a plurality of electrodes 13 coupled to terminals of the electronic components 20 are formed in mounting regions 12 of the first main surface S1 of the board 10 over which the electronic components 20 are mounted. The electrodes 13 may be formed by patterning a conductive film, such as, for example, a copper foil.

As illustrated in FIG. 4B, the antennas 30 are formed over the second main surface S2 of the board 10. The antennas 30 correspond to the electronic components 20 mounted over the first main surface S1 of the board 10 on a one-to-one basis and are disposed so as to form a matrix corresponding to an arrangement of the electronic components 20. The antennas 30 may be formed by patterning a conductive film, such as, for example, a copper foil. Although FIG. 4B illustrates, as an example, a rectangular antenna pattern, the shape of the antennas 30 may be appropriately determined so as to obtain a desired radiation performance. The antennas 30 are coupled to the respective electronic components 20 through vias 11 and the electrodes 13 that penetrate through the board 10.

Each of the electronic components 20 includes a signal processing circuit that processes signals transmitted and received through a corresponding one of the antennas 30. The signal processing circuit may include, for example, a transmission circuit and a reception circuit, and the transmission circuit and the reception circuit may include, for example, a phase shifter and an amplifier. Each of the electronic components 20 is, for example, in the form of fan-out wafer level package (FOWLP) and is coupled to the electrodes 13 formed over the first main surface S1 of the board 10 through a plurality of solder bumps 21 formed over a surface joined to the board 10. The signal processing circuit processes signals of comparatively high frequencies, and the electronic component 20 generates a comparatively high heat during operation. The electronic component 20 is an example of a heat generating member in the disclosed technique.

The frame 40 having a grid shape is provided over the first main surface S1 of the board 10 along the electronic components 20 that are arranged. For example, the frame 40 is a grid-shaped member that extends through spaces between the electronic components 20 adjacent to each other in the longitudinal direction and the transverse direction so as to separate the electronic components 20 from each other, Preferably, the frame 40 has a rigidity higher than the rigidity of the board 10. Thus, the frame 40 may function as a reinforcing member that suppresses deformation (bending) of the board 10 caused by heat generation of the electronic components 20. Preferably, the Young's modulus of the frame 40 is, for example, 100 GPa or more. Preferably, the thermal expansion coefficient of the frame 40 is, for example, 20×10⁻⁶/K or smaller. When the Young's modulus and the thermal expansion coefficient of the frame 40 are in the above-described ranges, the effect of suppressing the deformation of the board 10 by the frame 40 may be increased. Preferably, as the material of the frame 40, for example, metal such as stainless steel (SUS), copper, tungsten, or molybdenum or a ceramic such as alumina, zirconia, or silicon carbide may be used. Alternatively, diamond or sapphire may be used.

As illustrated in FIG. 5A, the frame 40 may have a structure in which first bar-shaped members 40A extending in the longitudinal direction and second bar-shaped members 408 extending in the transverse direction are separately formed. For example, as illustrated in FIGS. 5A and 5B, the frame 40 may be formed by combining the first bar-shaped members 40A and the second bar-shaped members 40B with each other such that the lengthwise direction of the first bar-shaped members 40A and the lengthwise direction of the second bar-shaped members 40B intersect each other. The first bar-shaped members 40A may each have cuts 41 at intersections with the second bar-shaped members 40B and the second bar-shaped members 40B may each have cuts 41 at intersections with the first bar-shaped members 40A, and the cuts 41 of the first bar-shaped members 40A may be fitted into the cuts 41 of the second bar-shaped members 40B or the cuts 41 of the second bar-shaped members 40B may be fitted into the cuts 41 of the first bar-shaped members 40k thereby to form the grid-shaped frame 40.

When the frame 40 is formed by combining a plurality of bar-shaped members with each other as described above, the manufacture of the frame 40 is facilitated compared to the case where the frame 40 is formed as a single unit. Furthermore, the size and number of squares of the grid of the frame 40 may be flexibly varied.

As illustrated in FIG. 4A, a grid-shaped conductor pattern 14 corresponding to the grid shape of the frame 40 is formed in a region where the frame 40 is mounted over the first main surface S1 of the board 10. The frame 40 is joined to the first main surface S1 of the board 10 by applying a joining material such as solder to the conductor pattern 14. A surface of the grid-shaped conductor pattern 14 may be plated with gold so as to improve the wettability of the solder used for joining to the frame 40.

The lid 50 covers the first main surface S1 of the board 10. The lid 50 has a recess on a side facing the board 10. The electronic components 20 are housed in a space defined by the recess of the lid 50 and the first main surface S1 of the board 10. Preferably, the lid 50 is formed of a material having a comparatively high thermal conductivity such as silver, copper, aluminum, or alumina.

Each of the electronic components 20 is joined to a surface S3 of the lid 50 facing the board 10 with a joining material 60 having a comparatively high thermal conductivity interposed therebetween. For example, each of the electronic components 20 is thermally coupled to the lid 50. Preferably, as the joining material 60, materials having a comparatively high thermal conductivity such as, for example, solder and thermal grease are used. An outer peripheral portion of the lid 50 is joined to the first main surface S1 of the board 10 with a joining material 61 interposed therebetween. A conductor pattern (not illustrated) used for joining to the lid 50 may be formed over the first main surface S1 of the board 10 at a position corresponding to the outer peripheral portion of the lid 50. In this case, solder may be used as the joining material 61. Alternatively, a resin adhesive may be used as the joining material 61.

Hereinafter, a method of manufacturing the electronic module 1 is described. FIGS. 6A to 6D are sectional views illustrating an example of the method of manufacturing the electronic module 1.

First, the board 10 is prepared. The electrodes 13 (see FIG. 4A) and the grid-shaped conductor pattern 14 (see FIG. 4A) are formed over the first main surface S1 of the board 10, and the antennas 30 are formed over the second main surface S2 of the board 10 (FIG. 6A). The surface of the grid-shaped conductor pattern 14 may be plated with gold.

Next, the electronic components 20 are mounted over the first main surface S1 of the board 10 (FIG. 6B). Each of the electronic components 20 are aligned with the electrodes 13 formed over the first main surface S1 of the board 10 (see FIG. 4A).

Next, the frame 40 is mounted over the first main surface S1 of the board 10 (FIG. 6C). The frame 40 is aligned with the grid-shaped conductor pattern 14 formed over the first main surface S1 of the board 10 (see FIG. 4A).

Next, the joining material 60 including materials having a comparatively high thermal conductivity such as solder and thermal grease is formed over surfaces of the electronic components 20 opposite the surface joined to the board 10. Then, the lid 50 is mounted over the first main surface S1 of the board 10 (FIG. 6D). The conductor pattern (not illustrated) is formed at a position of the first main surface S1 of the board 10 corresponding to the outer peripheral portion of the lid 50. The lid 50 is aligned with this conductor pattern. A surface of the lid 50 in contact with the board 10 is plated with solder as the joining material 61. The surface S3 of the lid 50 facing the board 10 is in contact with each of the electronic components 20 with the joining material 60 interposed therebetween and in contact with a surface (upper surface) of the frame 40 opposite a surface (lower surface) in contact with the board 10. The surface (lower surface) of the frame 40 in contact with the board 10 and the surface (upper surface) of the frame 40 in contact with the lid 50 are each plated with solder. Then, a reflow process is performed on the board 10 over which the electronic components 20 and the lid 50 are mounted. Thus, the electronic components 20, the frame 40, and the lid 50 are joined to the board 10, and the electronic components 20 and the frame 40 are joined to the lid 50. The electronic components 20 are electrically coupled to the respective antennas 30 formed over the second main surface S2 of the board 10 through the vias 11 penetrating through the board 10.

FIG. 7 is a sectional view illustrating an example of a configuration of an electronic module 1X according to a comparative example. The electronic module 1X according to the comparative example does not include the frame 40 included in the electronic module 1 according to the embodiment of the disclosed technique. In the electronic module 1X according to the comparative example, when the amount of heat generation of the electronic components 20 mounted over the board 10 increases, the board 10 may be deformed (bent) by the difference in thermal expansion coefficient between the electronic components 20 and the board 10, thereby breaking the joining between the lid 50 and the electronic components 20. As a result, the thermal dissipation function of the lid 50 is not necessarily effectively produced, and accordingly, the electronic components 20 may be damaged by the heat generation.

In contrast, in the electronic module 1 according to the embodiment of the disclosed technique, the grid-shaped frame 40 along the electronic components 20 that are arranged is joined to the first main surface S1 of the board 10. The frame 40 may function as the reinforcing member that increases the rigidity of the board 10 to suppress the deformation (bending) of the board 10 caused by the heat generation of the electronic components 20. Thus, the joining between the lid 50 and the electronic components 20 may be maintained, the thermal dissipation function of the lid 50 may be effectively produced, and the risk of damaging the electronic components 20 may be reduced. The frame 40 is joined not only to the board 10 but also to the lid 50. Thus, the reinforcing function of the frame 40 may be further improved, and accordingly, the effect of suppressing the deformation of the board 10 may be increased. The frame 40 has a grid shape along the electronic components 20 that are arranged. Thus, the entire region of the board 10 may be uniformly reinforced.

The effect of suppressing the deformation of the board 10 by using the frame 40 was verified by a simulation. FIG. 8 is a diagram illustrating a simulation model 1M of the electronic module 1 according to the embodiment of the disclosed technique. In the simulation model 1M, silicon heat generating bodies 20M that has a size of 5×5×0.8 mm and simulate the electronic components 20 were mounted in a four-by-six arrangement over a board 10M assumed to be a glass epoxy resin having a size of 130×100×0.8 mm. A frame 40M is assumed to be formed of stainless steel (Example 1) or alumina (Example 2). Although an element corresponding to the lid 50 is omitted from FIG. 8, the simulation model 1M is configured such that the board 10M is covered with a lid assumed to be formed of copper. A side E of the board 10M was bound as a secured end and the ambient temperature was increased from 25 to 100° C. Under these conditions, the amount of deformation from the secured end was calculated at a position where the deformation of the board 10M is largest. As the comparative example, a model of the electronic module without a frame was fabricated, and was subjected to a similar simulation. The results are provided in Table 1 below.

TABLE 1

| | | | Comparative |
|---|---|---|---|
| | Example 1 | Example 2 | example |
| Lid | Copper | Copper | Copper |
| Board | Glass | Glass | Glass |
| | epoxy | epoxy | epoxy |
| Electronic component | Silicon | Silicon | Silicon |
| Frame | Stainless steel | Alumina | — |
| Deformation amount [mm] | 1.6 | 0.9 | 1.8 |

In the model according to Example 1 including the frame 40M formed of stainless steel, the deformation amount of the board 10M is reduced by 0.2 mm compared to the model according to the comparative example without the frame. In the model according to Example 2 including the frame 40M formed of alumina, the deformation amount of the board 10M is reduced by 0.9 mm compared to the model according to the comparative example without the frame.

FIG. 9 is a graph illustrating the relationship between the Young's modulus of the frame 40M and a deformation amount improvement rate with the board 10M derived by using the simulation model 1M. FIG. 10 is a graph illustrating the relationship between the thermal expansion coefficient of the frame 40M and a deformation amount improvement rate with the board 10M derived by using the simulation model 1M. When the side E of the board 10M is bound as the secured end and the ambient temperature is increased from 25 to 100° C., the deformation amount, from the secured end, at a position where the deformation of the board 10M is largest is denoted by ΔL1 and the deformation amount of the comparative example is denoted by ΔL2 (=1.8 mm). At this time, a deformation amount reduction rate R is given by the following equation (1):

R=(ΔL2−ΔL1)/ΔL2 (1)

For example, when the deformation amount reduction rate R is a positive value, it is indicated that the deformation amount of the board 10M is smaller than that of the comparative example. When the deformation amount reduction rate R is a negative value, it is indicated that the deformation amount of the board 10M is greater than that of the comparative example.

As illustrated in FIG. 9, when the Young's modulus of the frame 40M is 100 GPa or greater, the deformation amount of the board 10M is smaller than that of the comparative example. As illustrated in FIG. 10, when the thermal expansion coefficient of the frame 40M is 20×10⁻⁶ [1/K] or smaller, the deformation amount of the board 10M is smaller than that of the comparative example. Accordingly, it is preferable that the frame 40 be formed of a material having a Young's modulus of 100 GPa or greater and a thermal expansion coefficient of 20×10⁻⁶/K or smaller.

### Second Embodiment

FIG. 11 is a plan view illustrating an example of a configuration of an electronic module 1A according to a second embodiment of the disclosed technique. Although the electronic module 1A according to the second embodiment includes the lid 50 similar to that of the electronic module 1 according to the first embodiment, the lid 50 is omitted from FIG. 11.

The electronic module 1A according to the second embodiment includes the board 10 having a hexagonal external shape. The frame 40 includes portions 40C and multiple annular portions 40D, 40E. The portions 40C radially extend from the center toward the vertices of the board 10. The annular portions 40D, 10E are centered at the center of the board 10 and disposed parallel to the sides of the board 10. For example, the frame 40 is in the form of a mesh shape in the electronic module 1A. The electronic components 20 are disposed in regions separated by the portions 40C, 40D, 40E of the frame 40. The orientation of the electronic components 20 may vary from region to region.

In the electronic module 1A according to the present embodiment, similarly to the electronic module 1 according to the first embodiment, deformation of the board 10 caused by the heat generation of the electronic component 20 as the heat generating member may be suppressed. Although the board 10 having a hexagonal external shape is described as an example for the present embodiment, the external shape of the board 10 may be any polygon having five or more angles (vertices).

### Third Embodiment

FIG. 12 is a perspective view illustrating an example of a configuration of an electronic device 2 according to a third embodiment of the disclosed technique. FIG. 13 is a block diagram illustrating an example of a functional configuration of the electronic device 2.

The electronic device 2 is included in a communication device that performs wireless communication and includes a housing 70, a baseband board 80, and an electronic module 1. As the electronic module 1, the electronic module 1 according to the first embodiment of the disclosed technique or the electronic module 1A according to the second embodiment of the disclosed technique may be used. The baseband board 80 is housed in the housing 70. The electronic module 1 is attached to a surface of the housing 70 such that the antennas 30 face outward.

As illustrated in FIG. 13, the electronic device 2 functioning as the communication device functionally includes an RF unit 100 and a baseband unit 110. The baseband unit 110 is a block that handles digital signals before modulation or after demodulation. The baseband unit 110 includes a protocol stack 111, a transmission circuit 112, a reception circuit 113, digital to analog (DA) converters 114, and analog to digital (AD) converters 115. The protocol stack 111 performs, for example, retransmission control, control of transmission timing, and control of acknowledgement (ACK) in the case where an error occurs when the reception side decodes a bit string transmitted from the transmission side. The functions of the baseband unit 110 are implemented in the baseband board 80.

The RF unit 100 is a block that processes analog signals of a frequency band of an electromagnetic wave transmitted and received through an antenna 120. The RF unit includes a transmission circuit 101 and a reception circuit 102. The functions of the RF unit 100 are implemented in the electronic module 1. For example, the functions of the transmission circuit 101 and the reception circuit 102 included in the RF unit 100 are implemented in the electronic components 20 included in the electronic module 1, and the antenna 120 is realized by the antennas 30 included in the electronic module 1.

In the electronic device 2 according to the embodiments of the disclosed technique, deformation of the board 10 included in the electronic module 1 may be suppressed, thereby reducing the risk of damaging the electronic components 20. Thus, the reliability of the electronic device 2 may be improved.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic module, comprising:
a plurality of heat generating members provided over a first surface of a board;
a frame joined to the first surface of the board and provided between the plurality of heat generating members that are arranged, the frame being a grid-shaped frame or a mesh-shaped frame; and
a lid configured to cover the first surface of the board and thermally coupled to each of the plurality of heat generating members.

2. The electronic module according to claim 1, wherein
a second surface of the frame opposite a third surface of the frame joined to the first surface is joined to the lid.

3. The electronic module according to claim 1, wherein
the frame is formed of a material that has a Young's modulus of 100 GPa or greater and a thermal expansion coefficient of 20×10⁻⁶/K or smaller.

4. The electronic module according to claim 1, wherein
the frame includes
a first bar-shaped member, and
a second bar-shaped member that is separate from the first bar-shaped member, and wherein
the first bar-shaped member and the second bar-shaped member are combined with each other to form the frame such that a lengthwise direction of the first bar-shaped member and a lengthwise direction of the second bar-shaped member intersect each other.

5. The electronic module according to claim 1, further comprising:
a plurality of antennas that are provided over a fourth surface of the board opposite the first surface and that correspond to the plurality of heat generating members, respectively, wherein
each of the plurality of heat generating members are coupled to a corresponding one of the plurality of antennas and includes a circuit configured to process a signal transmitted and received through the antenna.

6. The electronic module according to claim 1, wherein
each of the plurality of heat generating members is a signal processing circuit.

7. An electronic module according to claim 1, wherein
the first surface of the board has a polygon shape having five or more angles and
the frame is the mesh-shaped frame.

8. An electronic device, comprising:
an electronic module including:
a plurality of heat generating members provided over a first surface of a board;
a frame joined to the first surface of the board and provided between the plurality of heat generating members that are arranged, the frame being a grid-shaped frame or a mesh-shaped frame; and
a lid configured to cover the first surface of the board and thermally coupled to each of the plurality of heat generating members; and
a housing to which the electronic module is attached.

9. The electronic device according to claim 8, wherein
a second surface of the frame opposite a third surface of the frame joined to the first surface is joined to the lid.

10. The electronic device according to claim 8, wherein
the frame is formed of a material that has a Young's modulus of 100 GPa or greater and a thermal expansion coefficient of 20×10⁻⁶/K or smaller.

11. The electronic device according to claim 8, wherein
the frame includes
a first bar-shaped member, and
a second bar-shaped member that is separate from the first bar-shaped member, and wherein
the first bar-shaped member and the second bar-shaped member are combined with each other to form the frame such that a lengthwise direction of the first bar-shaped member and a lengthwise direction of the second bar-shaped member intersect each other.

12. The electronic device according to claim 8, Further comprising:
a plurality of antennas that are provided over a fourth surface of the board opposite the first surface and that correspond to the plurality of heat generating members, respectively, wherein
each of the plurality of heat generating members is coupled to a corresponding one of the plurality of antennas and includes a circuit configured to process a signal transmitted and received through the antenna.

13. The electronic module according to claim 8, wherein
each of the plurality of heat generating members is a signal processing circuit.

14. An electronic device, comprising:
an electronic module; and
a housing to which the electronic module is attached, wherein;
the electronic module includes:
a plurality of heat generating members provided over a first surface of a board which has a polygon shape having five or more angles;
a mesh-shaped frame joined to the first surface of the board and provided between the plurality of heat generating members that are arranged; and
a lid configured to cover the first surface of the board and thermally coupled to each of the plurality of heat generating members.

15. The electronic module according to claim 14, wherein
each of the plurality of heat generating members is a signal processing circuit.
